(19) United States
(12) Patent Application Publication
(10) Pub. No.: US 2025/0290227 A1
(43) Pub. Date: Sep. 18, 2025

(54) DOPANT SUPPLY APPARATUS AND INGOT GROWTH APPARATUS INCLUDING THE SAME

(71) Applicant: HANWHA SOLUTIONS CORPORATION, Seoul (KR)

(72) Inventors: Sang Woong KIM, Seoul (KR); Yang Kyu KIM, Seoul (KR)

(73) Assignee: HANWHA SOLUTIONS CORPORATION, Seoul (KR)

(21) Appl. No.: 19/070,681

(22) Filed: Mar. 5, 2025

(30) Foreign Application Priority Data
Mar. 12, 2024 (KR) 10-2024-0034747

(51) Int. Cl. C30B 29/06; C30B 15/04; C30B 15/14; C30B 35/00

(52) U.S. Cl. CPC C30B 29/06; C30B 15/04; C30B 15/14; C30B 35/005

(57) ABSTRACT

An ingot growth apparatus includes an ingot growth furnace, an auxiliary melting furnace that supplies molten silicon to the ingot growth furnace, a silicon feeder that supplies solid silicon to the auxiliary melting furnace, and a dopant supply apparatus that supplies dopants to the auxiliary melting furnace, and the dopant supply apparatus can cool the dopants below its melting point so that the dopants discharged from the dopant supply apparatus remain in a solid state.

### CROSS-REFERENCE TO RELATED APPLICATION

This application claims priority from and the benefit under 35 USC § 119 of Korean Patent Application No. 10-2024-0034747, filed on Mar. 12, 2024, in the Korean Intellectual Property Office, the entire disclosure of which is incorporated by reference for all purposes.

### BACKGROUND

### 1. Field

The present disclosure relates to a dopant supply apparatus and an ingot growth apparatus including the same.

### 2. Description of the Related Art

A Czochralski crystal growth method is a method of manufacturing a single crystalline silicon wafer, which is a raw material for semiconductors, in which silicon is placed in a crucible, which is heated to melt the silicon. In a state in which a single crystalline seed is brought into contact with the molten silicon, the single crystalline seed is raised upward while being rotated in one direction to grow an ingot having a predetermined diameter. Among the Czochralski crystal growth methods, a method of continuously injecting a silicon material into a crucible to grow an ingot is called a continuous growth Czochralski method. In a continuous growth Czochralski method of the related art, solid silicon (polysilicon) is input as a silicon material, and there are problems in that it takes time for the solid silicon to melt, and the ingot or crucible is contaminated due to particles included in the solid silicon.

Meanwhile, dopants, which are impurities, are input to an ingot growth apparatus in addition to silicon in order to grow an ingot. In general, dopants composed of gallium, phosphorus, or the like may be supplied to change the electrical and physical properties of a wafer. In the case of the continuous growth Czochralski method, the dopants should be continuously and quantitatively input into a crucible according to the input of silicon. However, a conventional ingot growth apparatus has a problem in that dopants are melted by heat generated in a melting furnace and input in a liquid state, causing loss or adversely affecting wafer quality.

The above-described information disclosed in the technology that is the background of the invention is only intended to improve the understanding of the background of the present disclosure, and therefore may include information that does not constitute the related art.

Related Art Document: Korean Patent Publication No. 10-1408664

### SUMMARY OF THE INVENTION

The present disclosure is directed to providing a dopant supply apparatus and an ingot growth apparatus including the same capable of cooling dopants and inputting the dopants in a solid state into a melting furnace.

The problems to be solved by the present disclosure are not limited to the problems that are mentioned above, and other problems that have not been mentioned can be clearly understood by those skilled in the art from the description below.

According to an aspect of the present disclosure, there is provided an ingot growth apparatus including an ingot growth furnace, an auxiliary melting furnace configured to supply molten silicon to the ingot growth furnace, a silicon feeder configured to supply solid silicon to the auxiliary melting furnace, and a dopant supply apparatus configured to supply dopants to the auxiliary melting furnace, wherein the dopant supply apparatus cools the dopants below its melting point so that the dopants discharged from the dopant supply apparatus remain in a solid state.

The dopant supply apparatus may include a plurality of cooling elements, the cooling elements being thermoelectric elements, and the plurality of cooling elements may be arranged around a passage through which the dopants are supplied from the dopant supply apparatus.

Each of the plurality of cooling elements may be disposed such that a heat absorption surface faces the dopants stored in the dopant supply apparatus and a heat generation surface faces a cooling fluid flowing inside the dopant supply apparatus.

The dopant supply apparatus may include a body, a supply unit located inside the body and configured to cool and store the dopants, the supply unit including a cooling element, a driving unit configured to operate the supply unit, and a supply pipe connected to the body, at least a part of the supply pipe being inserted into the auxiliary melting furnace so that the dopants supplied from the supply unit are discharged into the auxiliary melting furnace.

The supply unit may include a first plate having the cooling element attached thereto and including one or more first plate holes communicating with an inlet of the supply pipe and a second plate supported by the first plate and including a plurality of second plate holes each storing a plurality of dopants, and the second plate may be moved by the driving unit and the dopants stored in the second plate hole overlapping one or more first plate holes among the plurality of second plate holes may be discharged into the supply pipe.

The cooling element may be arranged around the inlet of the supply pipe and overlap at least some of the plurality of second plate holes.

The cooling element may include a plurality of cooling elements for each of the supply units, have a quadrangular flat plate shape, and overlap one or more of the second plate holes.

The cooling element may have a ring or circular arc shape to overlap the plurality of second plate holes.

According to another aspect of the present disclosure, there is provided a dopant supply apparatus including a body, a plurality of supply units accommodated in the body and configured to store dopants therein, the supply unit including a cooling element configured to cool the dopants, a plurality of driving units configured to independently rotate the plurality of supply units, and a supply pipe inserted into a lower surface of the body and communicating with the plurality of supply units to discharge the dopants supplied from the plurality of supply units, wherein each of the supply units includes a first plate having a plurality of cooling elements, which are thermoelectric elements, attached to a lower surface thereof and including a first plate hole communicating with an inlet of the supply pipe, the first plate being cooled by the plurality of cooling elements, and a second plate supported by an upper surface of the first plate and including a plurality of second plate holes each storing a plurality of dopants at an edge, the second plate being rotated by the driving unit.

The plurality of cooling elements may be arranged around the inlet of the supply pipe to overlap at least some of the plurality of second plate holes, and when the respective driving units operate, the second plates included in the respective supply units may rotate, and the dopants stored in the second plate hole communicating with the first plate hole among the plurality of second plate holes may be discharged to the inlet of the supply pipe through the first plate hole.

Other aspects, characteristics, and advantages other than those described above will become apparent from the following detailed description, claims, and drawings for implementing the invention.

### BRIEF DESCRIPTION OF THE DRAWINGS

The following drawings attached to the present specification illustrate embodiments of the present disclosure, and serve to help understand the technical idea of the present disclosure together with the description of the invention to be described below. The present disclosure is not limited to the matters described in the drawings:

FIG. 1 illustrates an ingot growth apparatus;

FIG. 2 illustrates an ingot growth furnace and an auxiliary melting furnace;

FIG. 3 illustrates the auxiliary melting furnace and a dopant supply apparatus;

FIG. 4 illustrates the auxiliary melting furnace and a silicon feeder;

FIG. 5 illustrates a dopant supply apparatus;

FIG. 6 illustrates an exploded perspective view of a body of the dopant supply apparatus;

FIG. 7 illustrates the inside of the dopant supply apparatus;

FIG. 8 illustrates an example of the dopant supply apparatus;

FIG. 9 illustrates another example of the dopant supply apparatus;

FIG. 10 illustrates an exploded perspective view of a supply unit; and

FIGS. 11 to 14 illustrate dispositions of the supply unit.

### DETAILED DESCRIPTION

The embodiments of the present disclosure may be understood with reference to the description of the invention and the accompanying drawings. Embodiments to be described have various modification examples and may be implemented in different forms, and the present disclosure is not limited to the embodiments described herein. Further, some or all of the characteristics of various embodiments of the present disclosure may be combined. The respective embodiments may be implemented independently of each other or in relation to each other. The described embodiments are provided as examples so that the present disclosure can be complete and thorough, and are intended to completely convey the spirit of the present disclosure to those skilled in the art to which the present disclosure pertains. The present disclosure may be replaced within all modifications, equivalents, and substitutions within the spirit and technical scope of the present disclosure. Therefore, processes, elements, and techniques that are not necessary for those skilled in the art for complete understanding of the embodiments of the present disclosure may not be described.

Throughout the accompanying drawings and the specification, the same reference numerals, letters, or combinations thereof indicate the same components, and thus, redundant descriptions are omitted unless otherwise stated. Further, parts that are not related to the description are omitted in order to clearly describe the present disclosure.

The relative sizes of elements, layers, and regions in the drawings may be exaggerated for clarity. Hatching and/or shading in the accompanying drawings is generally provided to clarify boundaries between adjacent elements. Therefore, the presence or absence of hatching or shading does not indicate a preferred form or requirement for a particular material, material property, dimension, ratio, commonality between drawing elements, and/or other characteristics, properties, or attributes of elements unless otherwise specified.

Various embodiments will be described herein with reference to cross-sectional examples that are schematic illustrations of embodiments and/or intermediate structures. Therefore, the shapes of the drawings may vary, for example, as a result of manufacturing technologies and/or tolerances. Further, the specific structural or functional descriptions disclosed herein are merely examples for describing embodiments according to the concept of the present disclosure. Accordingly, the embodiments disclosed herein should not be construed as being limited to the shapes of the illustrated regions, and include, for example, deviations in shapes due to manufacturing.

The regions illustrated in the drawings are schematic in nature and their shapes are not intended to illustrate the actual shapes of apparatus regions and are not intended to be limiting. Further, as will be appreciated by those skilled in the art, the described embodiments may be modified in various ways without departing from the spirit or scope of the present disclosure.

A number of specific details are set forth in the specification to provide a thorough understanding of the various embodiments. However, various embodiments may be implemented without these specific details or including one or more details. In other cases, well-known structures and apparatuses are illustrated in a block diagram form to avoid unnecessarily obscuring the various embodiments.

To facilitate the description herein, spatially relative terms such as “below,” “above,” “lower,” and “upper” may be used to describe a relationship between one element or feature and another element or feature, as illustrated in the drawings. The spatially relative terms are intended to encompass various orientations of an apparatus in use or operation in addition to orientations illustrated in the drawings. For example, when an apparatus in the drawing is flipped over, another element or feature described as “below” or “lower” is oriented “above” the other element or feature. Thus, exemplary terms “below” and “lower” may include both upward and downward directions. The apparatus may be oriented in different directions (for example, rotated 90 degrees or in other directions), and spatially relative descriptions used herein should be construed accordingly. Likewise, when it is described that a first part is disposed “above” a second part, it means that the first part is disposed above or below the second part.

Also, the expression “in plan view” means that an object is viewed from above, and the expression “in a schematic cross-sectional view” means that an object is cut vertically to take a schematic cross-section. The expression “in a side view” means that a first object may be above or below or on the side of a second object, and vice versa. Additionally, the term “overlapping” or “superimposing” may include layer, laminate, surface, extending, covering, partially covering, or any other suitable term that is understood or can be understood by those skilled in the art. The expression “does not overlap” may include meanings such as “apart from” or “spaced from,” and any other suitable equivalents recognized and understood by those skilled in the art. The terms “face” and “surface” may mean that a first object may directly or indirectly face a second object. When a third object is present between the first object and the second object, the first object and the second object may be understood to face each other but indirectly oppose each other.

When an element, layer, region, or component is referred to as being “formed on,” “connected to,” or “coupled to” another element, layer, region, or component, the element, layer, region, or component may be formed directly on the other element, layer, region, or component, may be formed on the other element, layer, region, or component, or may be indirectly formed on, connected to, or coupled to the other element, layer, region, or component. Further, “formed,” “connected,” or “coupled” may collectively refer to direct or indirect couplings or connections, and integral or non-integral couplings or connections of elements, layers, regions or components so that one or more elements, layers, regions, or components can be present. For example, when an element, layer, region, or component is referred to as being “electrically connected” or “electrically coupled” to another element, layer, region, or component, the element, layer, region, or component may be directly electrically connected or coupled to the other element, layer, region, or component, or other elements, layers, regions, or components may be present therebetween. However, “directly connected” or “directly coupled” means that one element is directly connected or coupled to another element without an intermediate component, or is on another element. Further, in the present specification, when a part of a layer, film, region, guide plate, or the like is formed on another part, the formation direction is not limited to an upper direction and includes that the part may be formed on the side or bottom. On the other hand, when a part of a layer, film, region, guide plate, or the like is formed “under” another part, this includes not only a case in which the part is “directly under” the other part, but also a case in which still another part is present between the part and the other part. Meanwhile, other expressions that describe a relationship between components, such as “between,” “directly between,” “adjacent to,” and “directly adjacent to” may be construed similarly. Also, when an element or layer is referred to as being “between” two elements or layers, the element or layer may be the only element between the two elements or layers, or there may be other elements therebetween.

For the purposes of the present specification, expressions such as “at least one or more” or “any one” do not limit the order of the individual elements. For example, expressions such as “at least one of X, Y, and Z,” “at least one of X, Y, or Z,” and “at least one selected from a group consisting of X, Y, and Z” may include X alone, Y alone, Z alone, or any combination of two or more of X, Y, and Z. Similarly, expressions such as “at least one of A and B” and “at least one of A or B” may include A, B, or A and B. In the present specification, the term “and/or” generally includes any combination of one or more associated list items. For example, an expression such as “A and/or B” may include A, B, or A and B.

Although the terms such as “first,” “second,” and “third” may be used herein to describe various elements, components, regions, layers, and/or sections, such elements, components, regions, layers, and/or sections are not limited by such terms. Such terms are used to distinguish one element, component, region, layer, or section from another element, component, region, layer, or section. Thus, a first element, component, region, layer, or section described below may be referred to as a second element, component, region, layer, or section without departing from the spirit and scope of the present disclosure. Describing an element as a “first” element does not require or imply the presence of a second element or other elements. The terms such as “first,” and “second” may also be used herein to distinguish different categories or sets of elements. For clarity, terms such as “first” and “second” may indicate “first category (or first set)” and “second category (or second set),” respectively.

The terms used herein are used only to describe specific embodiments and are not intended to limit the present disclosure. As used herein, singular forms are intended to include plural forms, and the plural forms are intended to include the singular forms unless otherwise explicitly stated in the context. The terms “comprise,” “include,” and “have,” when used herein, are meant to specify the presence of a specified feature, integer, or step. These expressions do not exclude the presence or addition of one or more other functions, steps, operations, components, and/or groups thereof.

When one or more embodiments may be implemented differently, specific processes may be performed differently from the described order. For example, two processes described in succession may be performed substantially simultaneously or in reverse order from the described order.

The terms “substantially,” “about,” “approximately,” and similar terms are used as terms of approximation, not as terms of degree, and mean that a measured or calculated value satisfies a range of inherent deviation (for example, a deviation range due to limitations of a measurement system). For example, “about” may refer to being within one or more standard deviations or within ±30%, 20%, 10%, or 5% of a specified value.

Unless otherwise defined, all terms used herein, including technical or scientific terms, have the same meaning as commonly understood by those skilled in the art to which the present disclosure belongs. Terms such as terms defined in commonly used dictionaries should be construed as having meanings consistent with their meaning in the related art and/or the context of the present specification, and should not be construed in an idealized or overly formal sense unless explicitly defined herein.

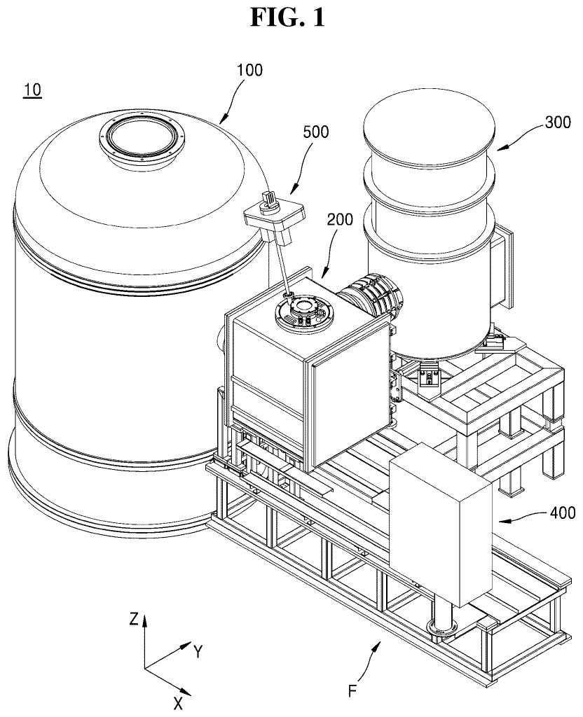

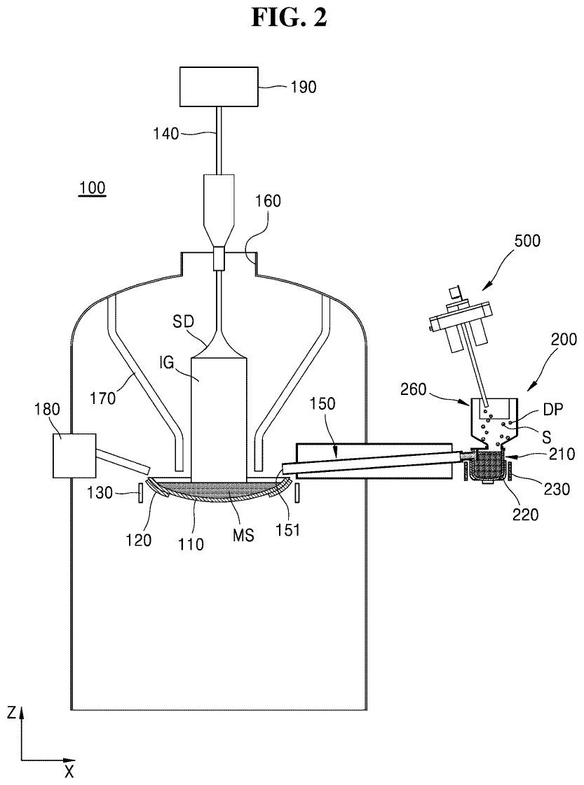

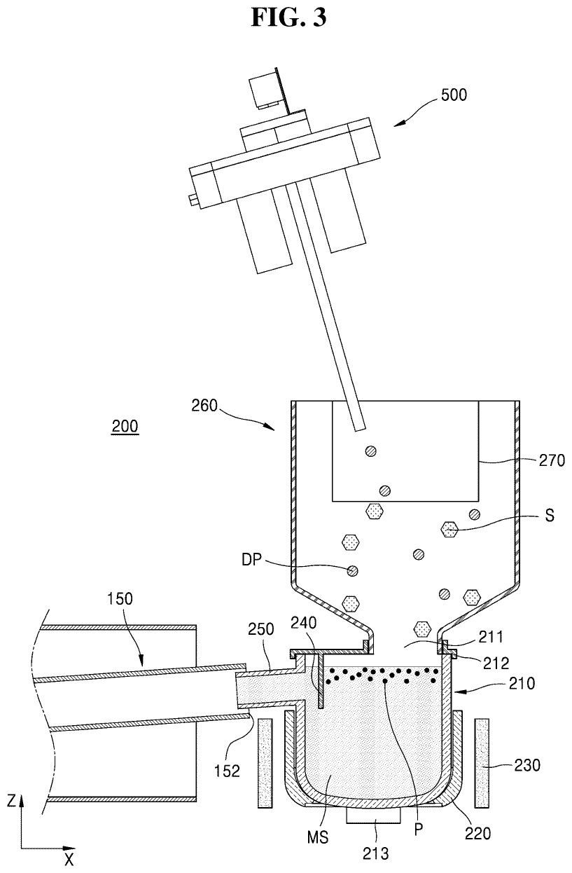

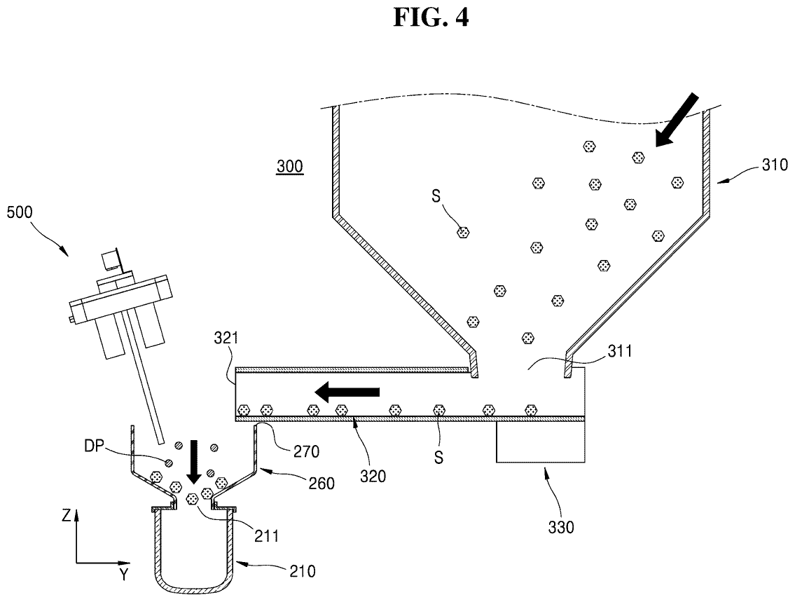

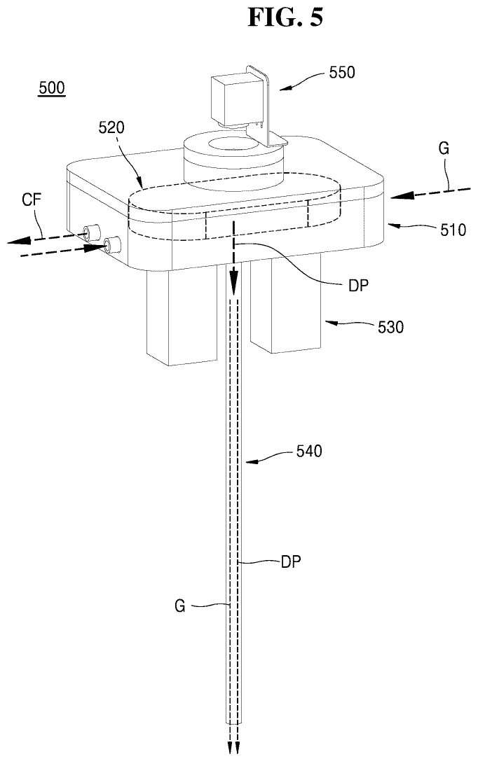

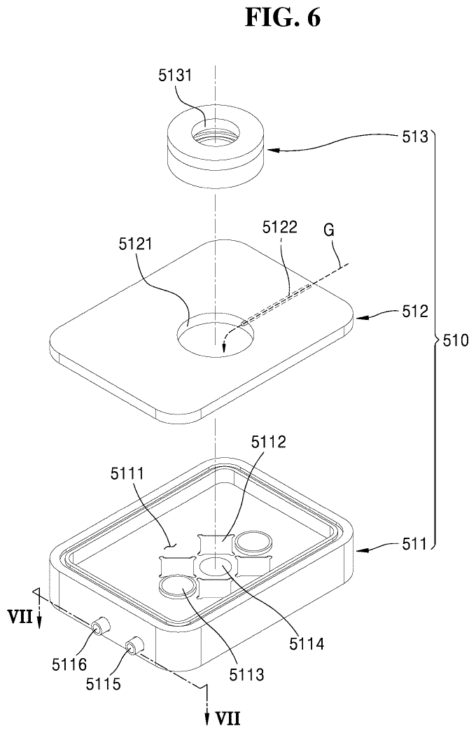

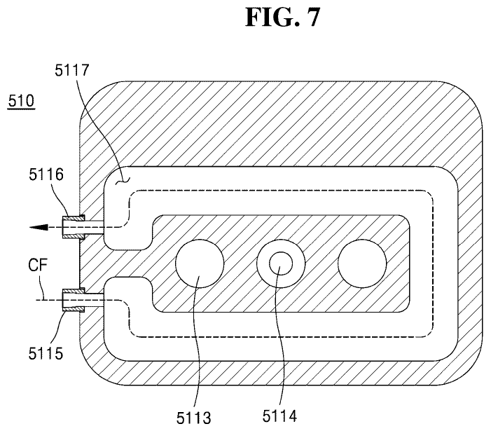

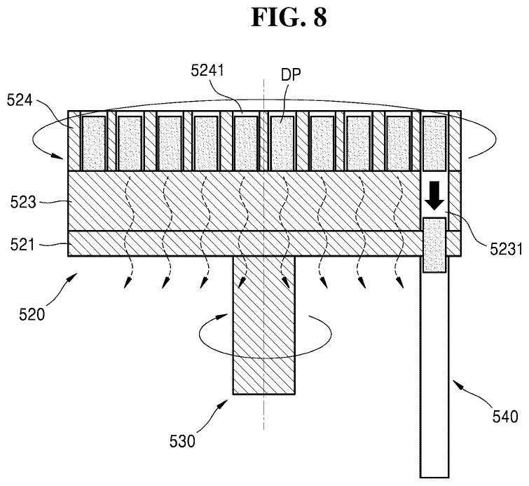

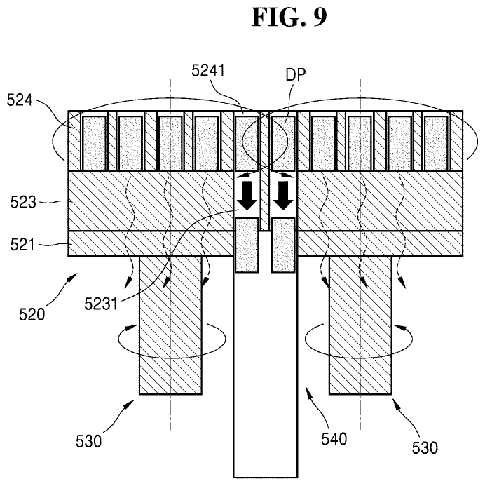

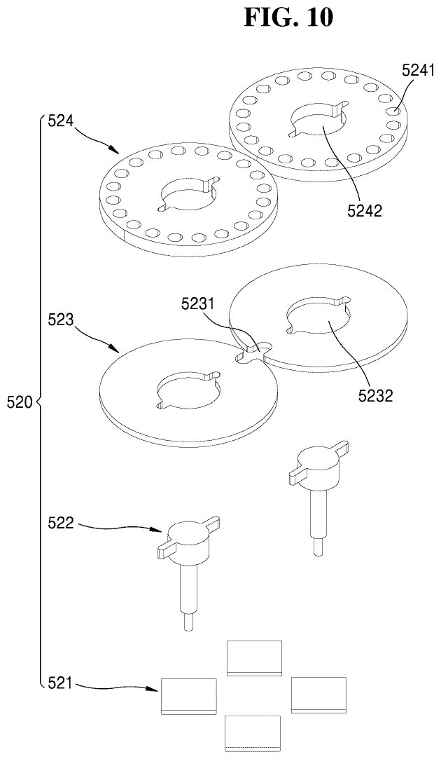

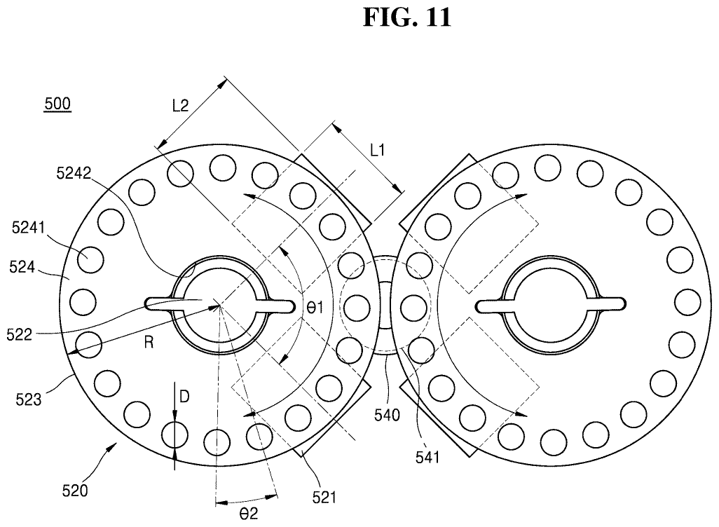

FIG. 1 illustrates an ingot growth apparatus 10, FIG. 2 illustrates an ingot growth furnace 100 and an auxiliary melting furnace 200, FIG. 3 illustrates the auxiliary melting furnace 200 and a dopant supply apparatus 500, FIG. 4 illustrates the auxiliary melting furnace 200 and a silicon feeder 300, FIG. 5 illustrates the dopant supply apparatus 500, FIG. 6 illustrates an exploded perspective view of a body 510 of the dopant supply apparatus 500, FIG. 7 illustrates the inside of the dopant supply apparatus 500, FIG. 8 illustrates an example of the dopant supply apparatus 500, FIG. 9 illustrates another example of the dopant supply apparatus 500, FIG. 10 illustrates an exploded perspective view of a supply unit 520, and FIGS. 11 to 14 illustrate dispositions of the supply unit 520.

The ingot growth apparatus 10 may be an apparatus for growing an ingot IG that is a raw material for a silicon wafer, and may be, for example, an apparatus for manufacturing a silicon (Si) or gallium arsenide (GaAs) single crystalline ingot. The ingot IG fabricated by the ingot growth apparatus 10 may be fabricated as a single crystalline silicon wafer for solar cells. For example, the ingot growth apparatus 10 may be a continuous single crystalline silicon ingot growth apparatus using a Czochralski method. For example, the ingot growth apparatus 10 may be a continuous growth type of ingot growth apparatus 10 that does not directly input solid silicon into the ingot growth furnace 100, but continuously supplies solid silicon S to the growth furnace in a state in which the solid silicon S is melted together with a dopants DP in the auxiliary melting furnace 200.

For example, the ingot growth apparatus 10 may include the ingot growth furnace 100, the auxiliary melting furnace 200 that supplies molten silicon MS to the ingot growth furnace 100, the silicon feeder 300 that supplies solid silicon S to the auxiliary melting furnace 200, and the dopant supply apparatus 500 that supplies the dopants DP to the auxiliary melting furnace 200. The dopant supply apparatus 500 of the ingot growth apparatus 10 may cool the dopants DP below its melting point so that the discharged dopants DP remains in a solid state.

The ingot growth apparatus 10 may include the ingot growth furnace 100, the auxiliary melting furnace 200, the silicon feeder 300, a controller 400, and the dopant supply apparatus 500.

The ingot growth furnace 100 may receive molten silicon MS from the auxiliary melting furnace 200 and grow the molten silicon MS into the ingot IG. The ingot growth furnace 100 may rotate the molten silicon MS in one direction while heating the molten silicon MS to a predetermined temperature to grow single crystalline silicon. The single crystalline silicon may be pulled vertically in the ingot growth furnace 100 and grown vertically. The inside of the ingot growth furnace 100 may maintain a vacuum or an inert gas atmosphere including helium or argon. Alternatively, the ingot growth furnace 100 may be directly connected to the silicon feeder 300 and may melt the solid silicon S supplied from the silicon feeder 300.

The ingot growth furnace 100 may include a main crucible 110, a first heating element 120, a first heater 130, a lifting wire 140, and a first transport channel 150.

The main crucible 110 may be located inside the ingot growth furnace 100 and the main crucible 110 may receive the molten silicon MS from the auxiliary melting furnace 200 and may heat the molten silicon MS to maintain the silicon in a molten state. For example, as illustrated in FIG. 2, the main crucible 110 may have a downward concave shape and the main crucible 110 may accommodate the molten silicon MS. The main crucible 110 may receive the molten silicon MS supplied from the auxiliary melting furnace 200 through the first transport channel 150 or may receive solid silicon supplied from the silicon feeder 300. The main crucible 110 may be made of a material with excellent heat resistance, such as quartz. The molten silicon MS accommodated in the main crucible 110 may be grown into the ingot IG and pulled out of the ingot growth furnace 100 through an opening 160 by the lifting wire 140.

The first heating element 120 may be in contact with the main crucible 110 or may be adjacent to the main crucible 110. The first heating element 120 may transfer heat applied from the first heater 130 to the main crucible 110. The first heating element 120 may provide thermal energy to the main crucible 110 to maintain the molten silicon MS inside the main crucible 110 in a liquid state. For example, as illustrated in FIG. 2, one or more first heating elements 120 may be disposed on the outer surface of the main crucible 110. The first heating element 120 may include a material having excellent thermal conductivity. For example, the first heating element 120 may include a carbon material having excellent thermal conductivity. The first heating element 120 may transfer the heat applied from the first heater 130 to the main crucible 110 to circulate the molten silicon MS accommodated in the main crucible 110 and adjust an oxygen concentration in the molten silicon MS. For example, the first heating element 120 may have a curvature corresponding to a lower surface of the main crucible 110 and may have a ring shape centered on a center of the main crucible 110.

The first heater 130 may heat the main crucible 110. For example, as illustrated in FIG. 2, the first heater 130 may be spaced apart from the main crucible 110 and located on the outer side of the first heating element 120 and may surround the main crucible 110. The first heater 130 is a resistive heater that generates heat to heat the main crucible 110 when current is applied. Alternatively, the first heater 130 may form a magnetic field to circulate the molten silicon MS accommodated in the main crucible 110 and adjust the oxygen concentration in the molten silicon MS. The first heater 130 may directly or indirectly heat the main crucible 110. The first heater 130 may be selectively operated depending on, for example, an amount of molten silicon MS accommodated in the main crucible 110 and/or a growth rate of the ingot IG.

The lifting wire 140 may be inserted into the ingot growth furnace 100 through the opening 160 formed in an upper portion of the ingot growth furnace 100, and the lifting wire 140 may have a lower end to which a seed SD is connected. The lifting wire 140 may be rotated and pulled at a predetermined speed by a lifting apparatus. The lifting wire 140 may be lowered by the lifting apparatus so that the seed SD comes into contact with the molten silicon MS in the main crucible 110, and may be raised while rotating in one direction. Accordingly, the ingot IG may grow downward from the seed SD connected to the lifting wire 140 and brought into contact with the molten silicon MS.

The first transport channel 150 is a passage that connects the ingot growth furnace 100 to the auxiliary melting furnace 200, and allows the molten silicon MS to move from the auxiliary melting furnace 200 to the ingot growth furnace 100. For example, as illustrated in FIG. 2, a part of the first transport channel 150 may be inserted into the ingot growth furnace 100, and one end (for example, an outlet 151) of the first transport channel 150 may be above the main crucible 110. Further, another part of the first transport channel 150 may be inserted into the auxiliary melting furnace 200, and the other end (for example, an inlet 152) may surround a second transport channel 250. When the ingot growth furnace 100 and the auxiliary melting furnace 200 are connected, the molten silicon MS melted in an auxiliary crucible 210 may be introduced into the first transport channel 150 through the second transport channel 250 and then discharged into the main crucible 110. For example, as illustrated in FIG. 2, the first transport channel 150 may be a square or circular pipe extending through a side of the ingot growth furnace 100 and may be inclined downward toward the main crucible 110 from the auxiliary crucible 210. Alternatively, in a state in which the ingot growth furnace 100 is directly connected to the silicon feeder 300 rather than to the auxiliary melting furnace 200, the first transport channel 150 may receive the solid silicon S from the silicon feeder 300. The solid silicon S may be introduced into the main crucible 110 through the outlet 151 and melted.

The first transport channel 150 may have the outlet 151 inside the ingot growth furnace 100 and the inlet 152 outside the ingot growth furnace 100. The first transport channel 150 may be inserted into the ingot growth furnace 100, the inlet 152 may be inside the auxiliary melting furnace 200 when the ingot growth furnace 100 is coupled with the auxiliary melting furnace 200, and the inlet 152 may be inside the silicon feeder 300 when the ingot growth furnace 100 is coupled with the silicon feeder 300.

The auxiliary melting furnace 200 may receive the solid silicon S from the silicon feeder 300, melt the solid silicon S, generate molten silicon MS, and supply the molten silicon MS to the ingot growth furnace 100. The auxiliary melting furnace 200 may have one side connected to the ingot growth furnace 100 and the other side connected to the silicon feeder 300. The auxiliary melting furnace 200 may be detachable from the ingot growth furnace 100 and the silicon feeder 300. The auxiliary melting furnace 200 may be connected to the dopant supply apparatus 500. For example, as illustrated in FIGS. 1 and 2, the auxiliary melting furnace 200 may have the dopant supply apparatus 500 mounted thereon and may receive the dopants DP from the dopant supply apparatus 500. For example, the auxiliary melting furnace 200 may be supported by a frame F, as illustrated in FIG. 1.

The auxiliary melting furnace 200 may include an auxiliary crucible 210, a second heating element 220, a second heater 230, a partition wall 240, the second transport channel 250, a first hopper 260, and a discharge port 270.

The auxiliary crucible 210 may be located within the auxiliary melting furnace 200 and may accommodate and melt the solid silicon S supplied from the silicon feeder 300. For example, as illustrated in FIG. 3, the auxiliary crucible 210 may have a U-shaped cross-section to accommodate the solid silicon S and the molten silicon MS. At least a part of an upper portion of the auxiliary crucible 210 may be covered by a cover 212 and may be connected to the first hopper 260 through a first inlet 211.

The second heating element 220 may be mounted on the auxiliary crucible 210 or located adjacent to the auxiliary crucible 210. The second heating element 220 may transfer the heat applied from the second heater 230 to the auxiliary crucible 210. The second heating element 220 may provide thermal energy to the auxiliary crucible 210 to melt the solid silicon S inside the auxiliary crucible 210 or maintain the molten silicon MS in a liquid state. The second heating element 220 may include a material having excellent thermal conductivity. For example, the second heating element 220 may include a material corresponding to the first heating element 120. The second heating element 220 may have a shape corresponding to the auxiliary crucible 210, may be in contact with an outer surface of the auxiliary crucible 210, and may surround a lower surface and a part of a side surface of the auxiliary crucible 210.

The second heater 230 may heat the auxiliary crucible 210. The second heater 230 may be spaced apart from the auxiliary crucible 210 and located on the outer side of the second heating element 220. For example, as illustrated in FIG. 3, the second heater 230 may have a cylindrical shape with a hollow center and open upper and lower portions so that the auxiliary crucible 210 and the second heating element 220 are located inside the second heater 230. The second heater 230 may include a heater corresponding to the first heater 130. The second heater 230 may directly or indirectly heat the auxiliary crucible 210. The second heater 230 may be selectively operated depending on an amount of molten silicon MS accommodated in the auxiliary crucible 210 and/or a growth rate of the ingot IG.

The partition wall 240 is disposed on one side of the auxiliary crucible 210 to prevent solid silicon and impurities P of the solid silicon from flowing into the ingot growth furnace 100 through the second transport channel 250. For example, as illustrated in FIG. 3, the partition wall 240 extends downward from an upper surface of the auxiliary crucible 210. The partition wall 240 may be biased toward the second transport channel 250 from a center of the auxiliary crucible 210. The partition wall 240 may prevent some of the solid silicon S and the impurities P introduced from the first hopper 260 from sinking below a surface of the molten silicon MS and flowing into the second transport channel 250.

The second transport channel 250 may be connected to the auxiliary crucible 210 and may transfer the molten silicon MS to the first transport channel 150. For example, as illustrated in FIG. 3, the second transport channel 250 may be connected to one side of the auxiliary crucible 210 adjacent to the partition wall 240 and inclined downward. The second transport channel 250 may be inserted into the inlet 152 of the first transport channel 150 and connected to the first transport channel 150.

The first hopper 260 is located above the auxiliary crucible 210 and supplies the solid silicon S supplied from the silicon feeder 300 to the auxiliary crucible 210. For example, the first hopper 260 may include the discharge port 270 connected to the silicon feeder 300, as illustrated in FIGS. 3 and 4. A solid silicon input path 320 of the silicon feeder 300 may be connected to the first hopper 260 through the discharge port 270, and the solid silicon S may be input into the first hopper 260. The first hopper 260 may have a cylindrical shape and may have a truncated cone shape with a lower portion inclined inward. The solid silicon discharged from the discharge port 270 may flow into the auxiliary crucible 210 through the first inlet 211 along a lower slope.

The silicon feeder 300 may supply the solid silicon S to the ingot growth furnace 100 or the auxiliary melting furnace 200. For example, as illustrated in FIG. 4, the silicon feeder 300 may be connected to the auxiliary melting furnace 200 to supply the solid silicon S to the auxiliary melting furnace 200, and the auxiliary melting furnace 200 may melt the solid silicon S and supply the molten silicon MS to the ingot growth furnace 100. Alternatively, the silicon feeder 300 may be directly connected to the ingot growth furnace 100 to supply the solid silicon S to the ingot growth furnace 100. For example, as illustrated in FIG. 1, the silicon feeder 300 may be supported by the frame F.

The silicon feeder 300 may include a second hopper 310, the solid silicon input path 320, and a transport member 330.

The solid silicon S input into the second hopper 310 may move to the solid silicon input path 320 through a second inlet 311. The solid silicon input path 320 may be an angular or tubular conduit extending in one direction, one end of which is connected to the second inlet 311, and an outlet 321 that is the other end may be inserted into the discharge port 270 of the auxiliary melting furnace 200. The transport member 330 may surround the solid silicon input path 320 or may be located below the solid silicon input path 320 to transport the solid silicon S. For example, the transport member 330 may be a vibration device and may be connected to a lower surface of the solid silicon input path 320 to vibrate the solid silicon input path 320 and move the solid silicon S inside.

The respective components of the ingot growth apparatus 10 may be modularized and assembled and disassembled in different combinations. For example, the ingot growth furnace 100, the auxiliary melting furnace 200, and the silicon feeder 300 may be freely assembled to and disassembled from each other. For example, the ingot growth furnace 100 and the auxiliary melting furnace 200 may be assembled to each other, the auxiliary melting furnace 200 and the silicon feeder 300 may be assembled to each other, or the ingot growth furnace 100 and the silicon feeder 300 may be assembled to each other. Further, the ingot growth furnace 100 and the auxiliary melting furnace 200, the auxiliary melting furnace 200 and the silicon feeder 300, or the ingot growth furnace 100 and the silicon feeder 300, which are assembled to each other, may be disassembled from each other. Further, the ingot growth furnace 100, the auxiliary melting furnace 200 and the silicon feeder 300 may all be assembled to each other. That is, the ingot growth apparatus 10 may be modularized for assembly and disassembly.

The controller 400 may be connected to the ingot growth furnace 100, the auxiliary melting furnace 200, the silicon feeder 300 and the dopant supply apparatus 500 in a wired or wireless manner to control the ingot growth furnace 100, the auxiliary melting furnace 200, the silicon feeder 300 and the dopant supply apparatus 500. For example, the controller 400 may control a pulling and lifting speed of the lifting wire 140 in the ingot growth furnace 100 and a temperature of the first heater 130. The controller 400 may control a temperature of the second heater 230 of the auxiliary melting furnace 200. The controller 400 may control an amount of solid silicon input by the silicon feeder 300. The controller 400 may control, for example, a timing, cycle, speed, and amount of the dopants DP supplied by the dopant supply apparatus 500. The controller 400 may be operated according to a program or algorithm that has been input in advance or may be operated according to instructions directly input from a user. For example, as illustrated in FIG. 1, the controller 400 may be supported by the frame F that supports the auxiliary melting furnace 200.

For the controller 400, a direct circuit structure that executes each control function through one or more microprocessors or other control devices, such as a memory, a processor, a logic circuit, and a look-up table, may be used. The controller 400 may be implemented as a part of a module, program, or code including one or more executable instructions for executing specific logic functions. The controller 400 may include or be implemented by a processor such as a central processing unit that executes functions, a microprocessor, and the like. The controller 400 may include a communication device capable of transmitting and receiving data to and from an external device or the like. The communication device may include one or more combinations of a digital modem, an RF modem, an antenna circuit, a Wi-Fi chip, related software, and firmware.

The dopant supply apparatus 500 may supply the dopants DP to the ingot growth apparatus 10. For example, as illustrated in FIG. 2, the dopant supply apparatus 500 is connected to the auxiliary melting furnace 200 and may supply the dopants DP (for example, gallium) to the auxiliary melting furnace 200. The dopant supply apparatus 500 may be mounted above an upper portion (for example, the first hopper 260) of the auxiliary melting furnace 200. The controller 400 may control, for example, an amount, speed, and cycle of the dopants DP supplied by the dopant supply apparatus 500. For example, the controller 400 may control the dopant supply apparatus 500 based on a dopant supply control factor including at least one of an amount of solid silicon S supplied from the silicon feeder 300 to the auxiliary melting furnace 200, an amount of molten silicon MS in the auxiliary melting furnace 200, an amount of molten silicon MS supplied from the auxiliary melting furnace 200 to the ingot growth furnace 100, and an interface height of the molten silicon MS in the main crucible 110.

The dopant supply apparatus 500 may supply the dopants DP in a solid state to the auxiliary melting furnace 200. For example, the dopant supply apparatus 500 may supply the dopants DP to the auxiliary melting furnace 200 in a state in which the dopants DP is maintained at a temperature lower than 29° C. (for example, at 20° C. or less), which is the melting point of the dopants DP. Here, the “solid state” may mean that the dopants DP remains in a solid state until the dopants DP leaves the dopant supply apparatus 500. For example, the dopants DP may remain in a solid state until a point in time when the dopants DP is discharged from a supply pipe 540 of the dopant supply apparatus 500 or a point in time when the dopants DP comes into contact with an interface of the molten silicon MS in the auxiliary melting furnace 200.

For example, the dopant supply apparatus 500 may include the body 510, the supply unit 520 that is located inside the body 510 and cools and stores the dopants DP and includes a cooling element 521, a driving unit 530 that operates the supply unit 520, and the supply pipe 540 that is at least partially inserted into the auxiliary melting furnace 200 and is connected to the body 510 and that discharges the dopants DP supplied from the supply unit 520 to the auxiliary melting furnace 200.

The dopant supply apparatus 500 may include the body 510, the supply unit 520, the driving unit 530, the supply pipe 540, and a camera 550.

The body 510 may hold and support other components (for example, the supply unit 520, the driving unit 530, the supply pipe 540, and the camera 550) of the dopant supply apparatus 500. For example, the body 510 may include an internal space, the supply unit 520 may be present in the internal space, and the driving unit 530 may be attached to a lower surface of the body 510 and connected to the supply unit 520, as illustrated in FIG. 5. The supply pipe 540 may be connected to the lower surface of the body 510 to communicate with the supply unit 520. Further, the camera 550 may be mounted on an upper surface of the body 510. The body 510 may cool the heat emitted from the cooling element 521 of the supply unit 520 and discharge the heat to the outside, thereby preventing the heat generated from the cooling element 521 from heating the dopants DP again or affecting other components of the dopant supply apparatus 500. For example, the body 510 may flow a cooling fluid CF under the supply unit 520 (for example, under the cooling element 521) to discharge the heat generated from the supply unit 520 to the outside. Further, the body 510 may introduce a gas G into the inside to prevent heat and byproducts (for example, oxides) from the auxiliary melting furnace 200 from flowing into the body 510 through the supply pipe 540. For example, an inert gas (for example, argon) may be introduced into the body 510 and then discharged downward along the supply pipe 540 so that the heat and byproducts of the auxiliary melting furnace 200 do not flow back into the body 510 along the supply pipe 540.

The body 510 may include a housing 511, a cover 512, and an adapter 513.

The housing 511 may define a space in which the supply unit 520 is accommodated, together with the cover 512. The housing 511 may have the cooling element 521 of the supply unit 520 provided therein and may be connected to the driving unit 530 and the supply pipe 540. Further, the gas G may flow into the supply pipe 540 through the inside of the housing 511. The housing 511 may have an open upper surface and may be covered with the cover 512.

The housing 511 may include an accommodation region 5111, a seat 5112, a first connection hole 5113, a second connection hole 5114, a cooling fluid inlet 5115, a cooling fluid outlet 5116, and a cooling flow path 5117.

The accommodation region 5111 may be an empty internal space of the housing 511, and the supply unit 520 may be accommodated in the accommodation region 5111. For example, as illustrated in FIG. 6, the accommodation region 5111 may be partitioned by a lower surface and an inner surface of the housing 511 and may be covered with the cover 512. The supply unit 520 may be accommodated inside the accommodation region 5111, and the accommodation region 5111 may communicate with the first connection hole 5113 and the second connection hole 5114. The dopants DP may be supplied from the supply unit 520 through the supply pipe 540 connected to the second connection hole 5114 communicating with the accommodation region 5111. Further, the gas G flowing through a gas flow path 5122 of the cover 512 may flow into the accommodation region 5111 and then move to the supply pipe 540 through the second connection hole 5114.

One or more seats 5112 may be formed in the accommodation region 5111, and at least a part of the supply unit 520 may be seated on the seats. For example, a plurality of (for example, four) seats 5112 may be formed on a lower surface of the accommodation region 5111 and may have a groove shape, as illustrated in FIG. 6. The seats 5112 may be formed to correspond to the cooling elements 521, and the cooling elements 521 may be seated on the seats 5112. For example, a plurality of seats 5112 may be formed around the second connection hole 5114 and formed with a depth corresponding to a thickness of the cooling elements 521, as illustrated in FIG. 6.

One or more first connection holes 5113 may be formed in the lower surface of the accommodation region 5111, and may be a portion in which the driving unit 530 and the supply unit 520 are connected to each other. For example, the first connection holes 5113 may be formed on both sides of the second connection hole 5114, and a connector 522 of the supply unit 520 may be inserted into the first connection hole 5113, as illustrated in FIG. 6.

The second connection hole 5114 may be formed in the lower surface of the accommodation region 5111 and may be a portion in which the supply pipe 540 is connected. For example, an inlet 541 of the supply pipe 540 may communicate with the second connection hole 5114. The second connection hole 5114 may overlap the supply unit 520, and the dopants DP discharged from the supply unit 520 may flow into the supply pipe 540 through the second connection hole 5114.

The cooling fluid inlet 5115 and the cooling fluid outlet 5116 may each be formed in the housing 511 and may communicate with the cooling flow path 5117 formed inside the housing 511. For example, as illustrated in FIG. 7, the cooling fluid inlet 5115 and the cooling fluid outlet 5116 may each be formed on one side of the housing 511 (for example, a surface corresponding to one of the short side portions of the housing 511). The cooling flow path 5117 may surround the first connection hole 5113 and the second connection hole 5114 and may be formed under the seats 5112 so that the cooling fluid CF flows under the supply unit 520. The cooling fluid CF flowing into the cooling fluid inlet 5115 may absorb the heat generated from the supply unit 520 (for example, the cooling element 521) while circulating around the housing 511 along the cooling flow path 5117, and then may be discharged through the cooling fluid outlet 5116. The cooling fluid CF is not limited to a specific liquid or gas, and may be water, for example.

The cover 512 may cover the open upper surface of the housing 511 and form the accommodation region 5111 together with the housing 511. The cover 512 may have a shape corresponding to the housing 511 and may guide the gas G introduced from the outside to the accommodation region 5111.

The cover 512 may include a cover hole 5121 and the gas flow path 5122.

The cover hole 5121 may be formed at a center of the cover 512 and may communicate with the adapter 513 and the second connection hole 5114. For example, the cover hole 5121 may be disposed to be coaxial with the adapter hole 5131 and the second connection hole 5114 or at least a part thereof may overlap the adapter hole 5131 and the second connection hole 5114. Accordingly, the camera 550 connected to the adapter 513 may check the inside of the second connection hole 5114, that is, the inside of the supply pipe 540, through the cover hole 5121. The cover hole 5121 may overlap the supply unit 520. For example, the cover hole 5121 may overlap at least a second plate hole 5241 overlapping the second connection hole 5114 among the plurality of second plate holes 5241 included in the supply unit 520. Therefore, a supply status of the dopants DP and a status of the inside of the auxiliary melting furnace 200 can be confirmed in real time through the camera 550.

The gas flow path 5122 may be formed inside the cover 512 and may have one end communicating with the outside of the cover 512 and the other end communicating with the cover hole 5121. The gas flow path 5122 may be connected to an external gas supply apparatus so that the gas G can be introduced. An inert gas G (for example, argon) may flow into the gas flow path 5122 and then flow into the accommodation region 5111 through the cover hole 5121. The gas G may move to the supply pipe 540 to prevent heat, gas, and other byproducts (such as oxides) generated in the auxiliary melting furnace 200 from flowing back into the supply pipe 540.

The adapter 513 may be mounted on an upper surface of the cover 512 and may support the camera 550. For example, as illustrated in FIG. 6, the adapter 513 may include an adapter hole 5131 at a center and may be mounted on the upper surface of the cover 512 so that the adapter hole 5131 is disposed to be coaxial with the cover hole 5121. For example, the adapter hole 5131, the cover hole 5121, and the second connection hole 5114 may all be coaxially disposed. The adapter hole 5131 may be opened and closed by an aperture provided in the adapter 513, and the user may open the adapter hole 5131 as needed to confirm the internal states of the supply pipe 540 and the auxiliary melting furnace 200 in real time using the camera 550.

The supply unit 520 may be located inside the body 510, may cool and store the dopants DP, and may include the cooling element 521. The supply unit 520 may supply the dopants DP to the auxiliary melting furnace 200 in a state in which the supply unit 520 maintains the dopants DP below its melting point. The supply unit 520 is operated by the driving unit 530, and the supply unit 520 may be operated to supply the dopants DP through the supply pipe 540 while the driving unit 530 is controlled at a predetermined cycle or by the controller 400. One or more supply units 520 may be accommodated inside the body 510 (for example, in the accommodation region 5111 of the housing 511), and each may be connected to the driving unit 530. For example, when the driving unit 530 operates, the supply unit 520 may rotate and the dopants DP stored in the supply unit 520 may be discharged into the supply pipe 540. The supply unit 520 may cool and store the dopants DP in a solid state and then discharge the dopants DP into the supply pipe 540. Therefore, it is possible to prevent a loss from occurring in a process of melting and supplying the dopants DP.

For example, as illustrated in FIG. 8, the supply unit 520 may include the cooling element 521, a first plate 523, and a second plate 524. The first plate 523 may be located between the cooling element 521 and the second plate 524, and may be cooled by the cooling element 521 to cool the second plate 524. For example, the first plate 523 may have a lower surface in contact with a heat absorption surface of the cooling element 521 and an upper surface in contact with a lower surface of the second plate 524. The first plate 523 may include a first plate hole 5231 communicating with the supply pipe 540. The second plate 524 may include the plurality of second plate holes 5241 that each store a plurality of dopants DP. The shapes of the first plate 523 and the second plate 524 are not limited to specific shapes and may have, for example, a thin disk shape. One or more cooling elements 521 may be attached to the lower surface of the first plate 523. When current is supplied to the cooling element 521, the heat absorption surface facing the lower surface of the first plate 523 is cooled and the heat may be discharged through an opposite surface. When the driving unit 530 operates, the first plate 523 and the cooling element 521 attached to the first plate 523 may be fixed, and the second plate 524 may rotate. The plurality of second plate holes 5241 may sequentially communicate with the first plate hole 5231, and the dopants DP stored in the second plate hole 5241 may be discharged to the supply pipe 540.

For example, there may be a plurality of (for example, two) supply units 520 and a plurality of (for example, two) driving units 530, as illustrated in FIG. 9. Each supply unit 520 may be operated individually (independently) by a corresponding driving unit 530, and the first plate hole 5231 of the first plate 523 included in each supply unit 520 may communicate with the inlet 541 of the supply pipe 540. Therefore, when each driving unit 530 operates, the dopants DP from each second plate 524 may be discharged sequentially or simultaneously into the supply pipe 540.

The supply unit 520 may include the cooling element 521, the connector 522, the first plate 523, and the second plate 524.

One or more cooling elements 521 are included in each supply unit 520, and may cool the dopants DP stored in the supply unit 520. For example, the cooling element 521 may be a thermoelectric element, and when current is supplied based on a Peltier effect, a heat absorption phenomenon occurs on a surface facing the dopants DP and a heat generation phenomenon occurs on the opposite surface, so that the dopants DP can be cooled. For example, the heat absorption surface of the cooling element 521 may be in contact with the lower surface of the first plate 523, and a heat generation surface may be seated on the seat 5112. The heat generation surface of the cooling element 521 may face the cooling flow path 5117 (for example, the cooling fluid CF flowing inside the dopant supply apparatus 500), and the cooling element 521 may be cooled by the cooling fluid CF flowing through the cooling flow path 5117.

The cooling element 521 may be disposed to overlap a region of the supply unit 520 in which the dopants DP is stored. For example, the cooling element 521 may be disposed below the second plate 524 and disposed to overlap the second plate hole 5241 in which the dopants DP is stored, as illustrated in FIG. 10. Therefore, it is possible to improve the cooling efficiency of the dopants DP by directly cooling the cooling element 521 and the dopants DP. The cooling element 521 may overlap all or some of the plurality of second plate holes 5241.

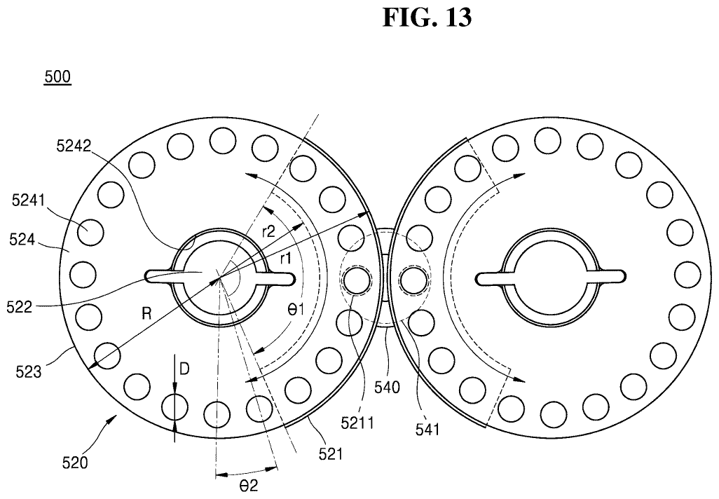

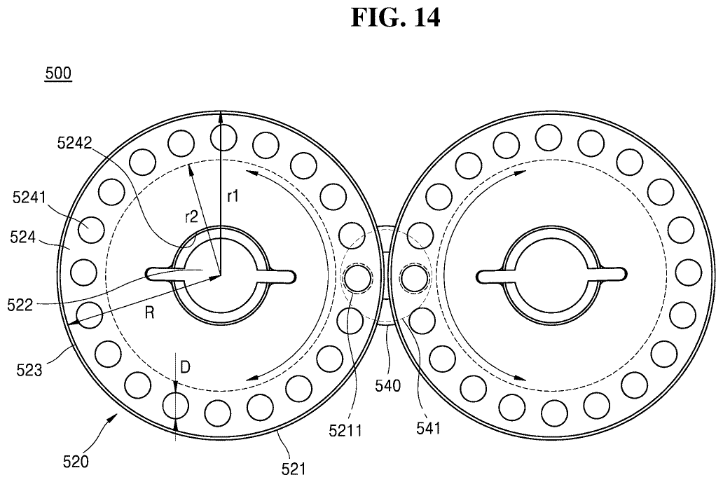

The cooling element 521 may be disposed around the inlet 541 of the supply pipe 540. For example, a plurality of cooling elements 521 may be disposed on the lower surface of the first plate 523 adjacent to the inlet 541. Since the inlet 541 of the supply pipe 540 is one of the regions where heat rises from the auxiliary melting furnace 200 and has a high temperature, the cooling element 521 may be disposed around the inlet 541 to efficiently cool the dopants DP. For example, as illustrated in FIG. 11, the plurality of cooling elements 521 may be located in a region between a center of the inlet 541 and a center of a second mounting hole 5242 of the second plate 524 to be spaced apart from the inlet 541 but adjacent to the inlet 541. Alternatively, as illustrated in FIGS. 13 and 14, the cooling element 521 may be disposed to cover at least a part of the inlet 541. The cooling element 521 may discharge the dopants DP into the inlet 541 through an opening 5211a. Since a part of the inlet 541 is covered by the cooling element 521, the heat rising from the inlet 541 may be partially blocked so that the dopants DP can be more stably maintained in a solid state.

An angle θ1 between the plurality of cooling elements 521 may be 60 degrees or more and 120 degrees or less. When θ1 is less than 60 degrees, a gap between the cooling elements 521 may become too small, causing the cooling elements 521 to interfere with each other or the cooling elements 521 to overlap the inlet 541 or the like. When θ1 exceeds 120 degrees, the cooling element 521 may move away from the inlet 541, causing the dopants DP stored in the second plate hole 5241 around the inlet 541 to be insufficiently cooled. For example, θ1 may be 70 degrees or more and 110 degrees or less, or θ1 may be 90 degrees.

An area of the cooling element 521 may be larger than that of any one of the second plate holes 5241. For example, any one of the cooling elements 521 may completely overlap at least one or more of the second plate holes 5241, and at least a part of the cooling element may extend outside the second plate hole 5241. At least a part of the cooling element 521 may protrude outward from the second plate 524. For example, as illustrated in FIGS. 11 to 14, a part of the cooling element 521 may protrude radially outward from the second plate 524. Therefore, the cooling element 521 may cool the dopants DP stored in any one of the second plate holes 5241 and the surroundings of the dopants DP, thereby stably maintaining the temperature of the dopants DP below its melting point.

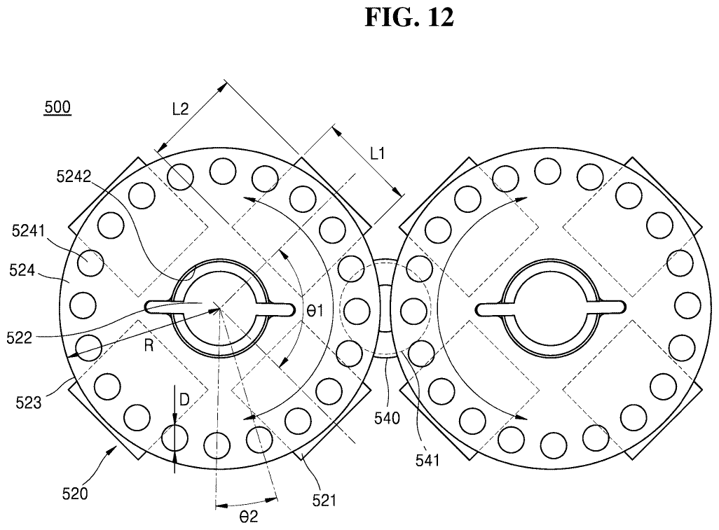

A shape of the cooling element 521 is not limited to a specific shape, and may have various shapes that overlap the dopants DP stored in the second plate hole 5241. For example, the cooling element 521 may be a square having a width L1 and a height L2, as illustrated in FIGS. 11 and 12. The width L1 and the height L2 may be greater than a diameter D of the second plate hole 5241, and may be the same or different from each other. For example, each of the width L1 and the height L2 may be 2 to 5 times the diameter D, so that one cooling element 521 may cover a plurality of second plate holes 5241. When the above ratio is less than 2, the area of the cooling element 521 may be too narrow, which may result in degraded cooling efficiency. When the above ratio exceeds 5, the cooling element 521 may come into contact with or interfere with other components (for example, the inlet 541 or the connector 522), which results in an increased heat generation area and, rather, degraded cooling efficiency. For example, the ratio may be 2.5 or more to less than 4.5

Alternatively, the cooling element 521 may have a band shape, as illustrated in FIG. 13. For example, the cooling element 521 may overlap a plurality of second plate holes 5241 and may overlap at least a part of the inlet 541. The cooling element 521 may have a circular arc shape or a crescent shape with an angle of θ1 between both ends. θ1 may be 60 degrees or more. When θ1 is less than 60 degrees, it is difficult to sufficiently cool the dopants DP disposed around the inlet 541. The cooling element 521 has an outer diameter r1 and an inner diameter r2, and the outer diameter r1 is greater than a radius R of the second plate 524, so that at least a part of the cooling element 521 can protrude outward from the second plate 524. For example, the outer diameter r1 may have a size such that the cooling element 521 does not come into contact with or interfere with the cooling elements 521 included in the other supply units 520. Further, the inner diameter r2 may be shorter than a shortest distance from a center of the second plate 524 to the second plate hole 5241 so that the cooling element 521 completely covers the second plate hole 5241. For example, the inner diameter r2 may be 40% or more and 80% or less of the radius R of the second plate 524. When the above ratio is less than 40%, the cooling element 521 covers a region far from the second plate hole 5241, resulting in excessive unnecessary cooling regions and degraded cooling efficiency. When the above ratio exceeds 80%, the cooling element 521 cannot stably cover the second plate hole 5241.

Since the cooling element 521 has such a shape and disposition, the dopants DP stored in the second plate hole 5241 around the inlet 541 can be cooled more reliably. In particular, the cooling elements 521 included in any one of the supply units 520 may be formed as a single piece without being segmented from each other. A region between the cooling elements 521 can also be reliably cooled compared to a case in which the cooling elements 521 are segmented. Further, the cooling elements 521 may not be disposed in other regions that do not overlap the second plate hole 5241, resulting in improved cooling efficiency of the dopants DP.

Alternatively, as illustrated in FIG. 14, the cooling element 521 may have a ring shape. For example, the cooling element 521 may overlap all the second plate holes 5241 included in one supply unit 520 and may overlap at least a part of the inlet 541. The cooling element 521 may have a ring shape having an outer diameter r1 and an inner diameter r2. The outer diameter r1 may be larger than the radius R of the second plate 524 so that at least a part of the cooling element 521 may protrude outward from the second plate 524. For example, the outer diameter r1 may have a size such that the cooling elements 521 included in different supply portions 520 do not come into contact with or interfere with each other. Further, the inner diameter r2 may be shorter than a shortest distance from the center of the second plate 524 to the second plate hole 5241 so that the cooling element 521 completely covers the second plate hole 5241. For example, the inner diameter r2 may be 40% or more and 80% or less of the radius R of the second plate 524. When the above ratio is less than 40%, the cooling element 521 covers a region far from the second plate hole 5241, resulting in an excessive unnecessary cooling region and degraded cooling efficiency. When the above ratio exceeds 80%, the cooling element 521 cannot stably cover the second plate hole 5241.

Since the cooling element 521 has such a shape and disposition, the dopants DP stored in the second plate hole 5241 around the inlet 541 can be cooled more reliably. In particular, since the cooling element 521 covers all of the plurality of second plate holes 5241, the dopants DP stored in the second plate hole 5241 located away from the inlet 541 may also be cooled. Therefore, it is possible to stably maintain the dopants DP stored in the second plate hole 5241 in a solid state until the second plate hole 5241 is positioned to overlap the inlet 541 due to the operation of the driving unit 530.

The cooling element 521 may include the opening 5211a. For example, one opening 5211a may be formed in each cooling element 521 to correspond to the inlet 541, as illustrated in FIGS. 13 and 14. The opening 5211a may be formed inside an inner circumference of the inlet 541 when viewed from above to overlap the inlet 541. Further, the opening 5211a may overlap the first plate hole 5231 of the first plate 523. The opening 5211a may have a larger size than the second plate hole 5241 and may completely cover the second plate hole 5241. Therefore, when the second plate 524 rotates and reaches a position in which the second plate hole 5241 overlaps the first plate hole 5231 and the opening 5211a, the dopants DP stored in the second plate hole 5241 may be discharged to the inlet 541 through the first plate hole 5231 and the opening 5211a.

The connector 522 may connect the supply unit 520 to the driving unit 530. For example, one end of the connector 522 may be connected to the driving unit 530 and the other end may be connected to the second plate 524 of the supply unit 520. When the driving unit 530 rotates, the connector 522 may rotate and the second plate 524 may rotate in a state in which the first plate 523 is fixed. Therefore, when the first plate hole 5231 of the first plate 523 overlaps the second plate hole 5241 of the second plate 524, the dopants DP stored in the second plate hole 5241 may be discharged through the first plate hole 5231.

The first plate 523 may be disposed between the second plate 524 and the cooling element 521, and may be in contact with the heat absorption surface of the cooling element 521. The first plate 523 has a shape corresponding to the second plate 524 (for example, a ring shape with a hole at a center) and may be cooled by the cooling element 521 to cool the second plate 524. For example, the first plate 523 may overlap the entire lower surface of the second plate 524. The first plate 523 has the connector 522 inserted therein and may not rotate due to the connector 522. That is, when the driving unit 530 operates and the second plate 524 rotates, the first plate 523 may be in a fixed state. Accordingly, when the second plate 524 rotates relative to the first plate 523, and the dopants DP stored in the second plate hole 5241 may be discharged into the supply pipe 540 through the first plate hole 5231. The first plate 523 may include a material having high thermal conductivity and not contaminating the dopants DP. For example, the first plate 523 may include an RSiC material. The cooling element 521 may be attached to the lower surface of the first plate 523.

The first plate 523 may include the first plate hole 5231 and a first mounting hole 5232.

The first plate hole 5231 may be formed at an edge of the first plate 523. In a state in which the supply unit 520 and the supply pipe 540 are assembled, the first plate hole 5231 may overlap the inlet 541 of the supply pipe 540, and may be formed inside the inner circumference of the inlet 541 when viewed from above. Accordingly, when the second plate 524 rotates and the second plate hole 5411 overlaps the first plate hole 5231, the dopants DP stored in the second plate hole 5411 may be discharged to the inlet 541 through the first plate hole 5231. For example, one first plate hole 5231 may be formed in each first plate 523, and the first plate holes 5231 may be formed to face each other, as illustrated in FIG. 10. Further, each first plate hole 5231 may be formed inside the inner circumference of the inlet 541 in plan view.

The first mounting hole 5232 is formed at a center of the first plate 523, and the connector 522 may be inserted into the first mounting hole 5232. The connector 522 inserted through the first mounting hole 5232 may be inserted into the second mounting hole 5242 of the second plate 524.

The second plate 524 may store the dopants DP and discharge the stored dopants DP into the supply pipe 540 while moving due to the driving unit 530. For example, the second plate 524 may have a disk shape with a center connected to the connector 522 and an edge where a plurality of dopants DP are stored. The lower surface of the second plate 524 may be in contact with the first plate 523, and the second plate 524 and the dopants DP stored in the second plate 524 may be cooled when the first plate 523 is cooled by the cooling element 521. The second plate 524 may be rotated at a regular cycle by the driving unit 530. For example, the second plate 524 may be rotated by an angle between adjacent second plate holes 5241 in a circumferential direction each time the driving unit 530 operates.

The second plate 524 may include the second plate holes 5241 and the second mounting hole 242.

The plurality of second plate holes 5241 may be formed at an edge of the second plate 524. One or more dopants DP may be stored in the second plate hole 5241. The second plate hole 5241 is open across an entire thickness of the second plate 524, and the dopants DP stored inside may be supported by an upper surface of the first plate 523. In a state in which the supply unit 520 and the supply pipe 540 are assembled, some of the plurality of second plate holes 5241 may discharge the dopants DP through the inlet 541. For example, one of the second plate holes 5241 of each second plate 524 may overlap the first plate hole 5231 and the inlet 541. For example, as illustrated in FIGS. 11 to 14, the respective second plate holes 5241 at positions where the respective second plates 524 face each other may overlap the first plate hole 5231 and the inlet 541, allowing the dopants DP to be discharged through the inlet 541. Thereafter, when the second plate 524 is rotated by the driving unit 530, the other adjacent second plate hole 5241 is positioned to overlap the first plate hole 5231 and the inlet 541, allowing the dopants DP stored in the second plate hole 5241 to be discharged into the supply pipe 540.

The number, size, and shape of the second plate holes 5241 may vary depending on a size and shape of the dopants DP, a capacity and specifications of the ingot growth apparatus 10, a capacity and specifications of the auxiliary melting furnace 200, and the like. For example, as illustrated in FIG. 11, the second plate hole 5241 may be a circular hole, and 18 second plate holes may be formed in each second plate 5241. Therefore, an angle θ2 between two adjacent second plate holes 5241 in a circumferential direction of the second plate 524 may be 18 degrees.

The second mounting hole 5242 may be formed in the center of the second plate 524 and the connector 522 may be inserted into the second mounting hole 5242. When an upper end of the connector 522 is coupled to the second mounting hole 5242 and the connector 522 rotates, the second plate 524 may also rotate.

The driving unit 530 may be connected to the supply unit 520 through the body 510. For example, as illustrated in FIG. 5, the driving unit 530 may be mounted on the lower surface of the body 510 and may be connected to the supply unit 520 accommodated inside the body 510. The driving unit 530 may be connected to the second plate 524 of the supply unit 520 through the connector 522. When the driving unit 530 rotates, the second plate 524 also rotates in the same direction, and the dopants DP stored in the second plate hole 5241 may be discharged into the supply pipe 540. For example, the driving unit 530 may be an electric motor. The driving unit 530 may be controlled by the controller 400 or operated according to a preset cycle. For example, the driving unit 530 may be a stepper motor that rotates 1.8 degrees per pulse.

The driving unit 530 may include a plurality of driving units 530. For example, as illustrated in FIG. 9, when the supply unit 520 includes a plurality of (for example, two) supply units 520, the driving unit 530 may also include a plurality of (for example, two) driving units 530. Each driving unit 530 is individually connected to each supply unit 520, and the operation of one driving unit 530 may not affect the other driving unit 530. The respective driving units 530 may operate simultaneously so that the respective supply units 520 discharge the dopants DP into the supply pipe 540 simultaneously. Alternatively, the respective driving units 530 may operate with a time delay so that the supply units 520 sequentially discharge the dopants DP into the supply pipe 540. Alternatively, one of the driving units 530 may operate first so that all the dopants DP included in the supply unit 520 corresponding to the driving unit 530 is discharged to the supply pipe 540, and then the other driving unit 530 may operate.

The supply pipe 540 may be connected to the body 510 and may be a passage through which the dopants DP discharged from the supply unit 520 moves to the auxiliary melting furnace 200. For example, as illustrated in FIG. 5, the supply pipe 540 may be a hollow tube connected to the lower surface of the body 510. The inlet 541 of the supply pipe 540 may communicate with the second connection hole 5114 of the housing 511. Therefore, the second plate 524 may rotate and the dopants DP stored in the second plate hole 5241 may be discharged through the inlet 541. In a state in which the dopant supply apparatus 500 is coupled to the auxiliary melting furnace 200, at least a part of the supply pipe 540 may be inserted into the auxiliary melting furnace 200 (for example, into the first hopper 260 as illustrated in FIG. 3).

The gas G may flow inside the supply pipe 540. For example, the gas G flowing into the gas flow path 5122 may enter through the inlet 541 and then flow along the supply pipe 540. Therefore, it is possible to prevent, for example, high-temperature gas and various byproducts of the auxiliary melting furnace 200 from flowing back along the supply pipe 540 and flowing into the body 510.

One or more cameras 550 may be included in the dopant supply apparatus 500 and may capture images and videos regarding the supply status and storage status of the dopants DP, and the status of the inside of the auxiliary melting furnace 200 and transmit the photographs and videos to the controller 400. For example, the camera 550 may be connected to an upper part of the body 510, as illustrated in FIG. 5. The camera 550 may be connected to the adapter 513 and may check the status of the supply unit 520 in the accommodation region 5111 through the adapter hole 5131 and the cover hole 5121. Further, the camera 550 may check the inside of the supply pipe 540 to check the supply status of the dopants DP and the inside of the auxiliary melting furnace 200. Alternatively, the camera 550 may include a thermal detection camera that can check the internal temperatures of the supply unit 520, the supply pipe 540, and the auxiliary melting furnace 200.

With the dopant supply apparatus and the ingot growth apparatus including the same according to various embodiments included in the present disclosure, it is possible to prevent the loss of dopant by maintaining the dopant in a solid state until the dopants are discharged. With the ingot growth apparatus according to various embodiments included in the present disclosure, it is possible to improve the cooling efficiency by arranging the cooling elements around the inlet through which the dopants are discharged.

However, the effects that can be obtained through the present disclosure are not limited to the effects described above, and other technical effects that are not mentioned can be clearly understood by those skilled in the art from the description of the invention described below.

Although the present disclosure has been described with reference to the embodiments illustrated in the drawings, these are merely examples. It should be readily understood by those skilled in the art that various modifications and equivalently different embodiments can be made from the embodiments. Therefore, the true technical protection scope of the present disclosure should be determined based on the appended claims.

The specific technical contents described in the embodiments are examples and do not limit the technical scope of the embodiments. Descriptions of general techniques and configurations of the related art may be omitted for concise and clear description of the invention. Further, the connections or absence of connections between the components illustrated in the drawings are exemplary representations of functional connections and/or physical or circuit connections, and may be expressed as various functional connections, physical connections, or circuit connections that are replaceable or added in an actual apparatus. Further, when there is no specific mention such as “essential” and “important,” a component may not be absolutely necessary for the application of the present disclosure.

The term “the” or similar designators described in the description of the invention and the claims may refer to both singular and plural forms unless specifically limited. Further, when a range is described in embodiments, the invention includes embodiments in which individual values within the range are applied (unless otherwise stated), and this is the same as describing each individual value constituting the range in the description of the invention. Further, unless there is an explicit description or contradiction of the order of steps constituting a method according to the embodiment, the steps may be performed in any appropriate order. The embodiments are not necessarily limited to the order in which the steps are described. The use of all examples or exemplary terms (for example, the like) in the embodiments is merely for the purpose of describing the embodiments in detail, and the scope of the embodiments is not limited by the examples or exemplary terms unless otherwise limited by the claims. Further, it will be understood by those skilled in the art that various modifications, combinations, and changes may be configured according to design conditions and factors within the scope of the appended claims or their equivalents.

What is claimed is:

1. An ingot growth apparatus comprising:
an ingot growth furnace;
an auxiliary melting furnace configured to supply molten silicon to the ingot growth furnace;
a silicon feeder configured to supply solid silicon to the auxiliary melting furnace; and
a dopant supply apparatus configured to supply dopants to the auxiliary melting furnace, wherein
the dopant supply apparatus cools the dopants below its melting point so that the dopants discharged from the dopant supply apparatus remain in a solid state.

2. The ingot growth apparatus of claim 1, wherein
the dopant supply apparatus includes a plurality of cooling elements, the cooling elements being thermoelectric elements, and
the plurality of cooling elements are arranged around a passage through which the dopants are supplied from the dopant supply apparatus.

3. The ingot growth apparatus of claim 2, wherein each of the plurality of cooling elements is disposed such that a heat absorption surface faces the dopants stored in the dopant supply apparatus and a heat generation surface faces a cooling fluid flowing inside the dopant supply apparatus.

4. The ingot growth apparatus of claim 1, wherein
the dopant supply apparatus includes
a body;
a supply unit located inside the body and configured to cool and store the dopants, the supply unit including a cooling element;
a driving unit configured to operate the supply unit; and
a supply pipe connected to the body, at least a part of the supply pipe being inserted into the auxiliary melting furnace so that the dopants supplied from the supply unit are discharged into the auxiliary melting furnace.

5. The ingot growth apparatus of claim 4, wherein
the supply unit includes
a first plate having the cooling element attached thereto and including one or more first plate holes communicating with an inlet of the supply pipe; and
a second plate supported by the first plate and including a plurality of second plate holes each storing a plurality of dopants, and
the second plate is moved by the driving unit, and the dopants stored in the second plate hole overlapping one or more first plate holes among the plurality of second plate holes is discharged into the supply pipe.

6. The dopant supply apparatus of claim 5, wherein the cooling element is disposed around the inlet of the supply pipe and overlaps at least some of the plurality of second plate holes.

7. The dopant supply apparatus of claim 6, wherein the cooling element includes a plurality of cooling elements for each of the supply units, has a quadrangular flat plate shape, and overlaps one or more of the second plate holes.

8. The dopant supply apparatus of claim 6, wherein the cooling element has a ring or circular arc shape to overlap the plurality of second plate holes.

9. A dopant supply apparatus comprising:
a body;
a plurality of supply units accommodated in the body and configured to store dopants therein, the supply unit including a cooling element configured to cool the dopants;
a plurality of driving units configured to independently rotate the plurality of supply units; and
a supply pipe inserted into a lower surface of the body and communicating with the plurality of supply units to discharge the dopants supplied from the plurality of supply units; wherein
each of the supply units includes
a first plate having a plurality of cooling elements, which are thermoelectric elements, attached to a lower surface thereof and including a first plate hole communicating with an inlet of the supply pipe, the first plate being cooled by the plurality of cooling elements; and
a second plate supported by an upper surface of the first plate and including a plurality of second plate holes each storing a plurality of dopants at an edge, the second plate being rotated by the driving unit.

10. The dopant supply apparatus of claim 9, wherein
the plurality of cooling elements are arranged around the inlet of the supply pipe to overlap at least some of the plurality of second plate holes, and
when the respective driving units operate, the second plates included in the respective supply units rotate, and the dopants stored in the second plate hole communicating with the first plate hole among the plurality of second plate holes are discharged to the inlet of the supply pipe through the first plate hole.
